(19) United States
(12) Patent Application Publication
(10) Pub. No.: US 2012/0142170 A1
(43) Pub. Date: Jun. 7, 2012

(54) METHOD OF FORMING PHOTONIC CRYSTALS

(76) Inventors: Jinghua Teng, Singapore (SG); Eo Lim, Singapore (SG); Soo Jin Chua, Singapore (SG); Soo Seng Nirman Ang, Singapore (SG)

(21) Appl. No.: 13/377,521

(22) PCT Filed: Jun. 9, 2010
(86) PCT No.: PCT/SG2010/000218

§ 371 Date: Feb. 21, 2012

Related U.S. Application Data
(60) Provisional application No. 61/185,690, filed on Jun. 10, 2009.

(51) Int. Cl. H01L 21/20

(52) U.S. Cl. 438/478; 257/E21.09

(57) ABSTRACT

According to an embodiment of the present invention, a method of forming photonic crystals is provided. The method includes: forming a layer arrangement on a support substrate. The layer arrangement includes a first partial layer arrangement and a second partial layer arrangement, wherein the second partial layer arrangement is disposed over the first partial layer arrangement, wherein each partial layer arrangement comprises a first layer and a second layer, wherein the second layer is disposed over the first layer, and wherein the material of the second layer has a different etching characteristic than the material of the first layer. The method further includes removing at least one portion of the second layer and removing the first layer, wherein forming the layer arrangement occurs prior to removing the at least one portion of the second layer and the first layer.

### FIELD

The invention relates to a method of forming photonic crystals.

### BACKGROUND

Photonic crystals are periodically structured materials that possess photonic band gaps: ranges of frequency in which light cannot propagate through the structure. As a result, they provide a degree of control over light, such as controlling photon localization and inhibition of spontaneous emission. Such properties can be exploited to create small-size, high-performance photonic devices, such as waveguides, splitters, microcavity laser, for optical communications, photonic integrated circuits and optical quantum computers.

Optical properties of photonic crystals are determined by parameters, such as: refractive index, dimension, size and periodicity of lattice structures within the photonic crystals. In optical communication at near IR and visible ranges, the feature size of the photonic crystal is usually of submicron range, e.g. below 300 nm, for semiconductors that are best for photonic crystal applications for their large refractive index and easy integration with other optoelectronics devices.

For photonic crystals built from semiconductors, two-dimensional (2D) photonic crystals are easy to fabricate. However, a 2D photonic crystal has light confined by total internal reflection in a direction perpendicular to the slab, which misses the most wanted complete photonic bandgap.

A 3D photonic crystal can have a complete photonic bandgap, providing the ability to completely inhibit light emission when it is not desired or alternatively concentrate it into a desirable form. However, research in 3D photonic crystals in semiconductors is hindered by semiconductor processing being a 2D thin film technology, making it difficult to organize a three-dimensional lattice in submicron scale.

There are a number of publications in 3D photonic crystal fabrication, including wafer bonding method, Micro-Electro-Mechanical Systems (MEMS) method, colloidal and nano-sphere method, repeated etch-regrowth method, direct etching of 1D multi-layer structures, etc. Every method has its own limitations.

The wafer bonding and MEMS methods require a lot of micro-manipulation and have alignment problems. They also involve very tedious processes.

Colloidal and nano-sphere methods are not suitable for complete bandgap formation due to the low refractive index materials used, like polystyrene (PS) or silica. It is also limited to an opal structure. Inverse opal structure was recently demonstrated by infiltration, but has been found unable to produce single crystals.

The repeated etch-regrowth method is a tedious process since it involves patterning, etching, surface planarization, and selective growth for every layer. It is more often used in silicon dioxide (SiO2) and poly silicon (poly-Si) systems to construct a 3D photonic crystal. It is not practical for Si or other III-V single crystal growth.

Another known method directly etches a one-dimensional (1D) multilayer structure. This method uses a 1D multi-layer structure, which can be single crystals or dielectrics. A 2D photonic crystal pattern on the top surface will be transferred to the whole multi-layer structure by direct plasma etching. However, for applications in optical or near IR wavelength, e.g. 1550 nm, it is extremely difficult, if not impossible to direct etch a feature in dimensions of around 200 nm to a depth enough for 3D confinement, e.g. 5 um. The aspect ratio is too high and holes sizes will gradually decrease and finally close at a certain depth. Also the refractive index difference between two semiconductor materials in a vertical direction is small, which results in weak light confinement in the vertical direction and no full photonic bandgap formation.

There is thus a need to provide a method to produce 3D photonic crystals easily from semiconductor crystals.

### SUMMARY OF THE INVENTION

According to an embodiment of the present invention, a method of forming photonic crystals is provided. The method includes: forming a layer arrangement on a support substrate. The layer arrangement includes a first partial layer arrangement and a second partial layer arrangement, wherein the second partial layer arrangement is disposed over the first partial layer arrangement, wherein each partial layer arrangement comprises a first layer and a second layer, wherein the second layer is disposed over the first layer, and wherein the material of the second layer has a different etching characteristic than the material of the first layer. The method further includes removing at least one portion of the second layer and removing the first layer, wherein forming the layer arrangement occurs prior to removing the at least one portion of the second layer and the first layer.

In a repeated etch-regrowth method, a first layer of semiconductor material is grown on a substrate and a lattice arrangement, which provides a photonic bandgap function, subsequently formed in the first layer. The lattice arrangement may be formed by patterning the first layer, etching the first layer according to the pattern and performing surface planarization to the resulting structure. A second layer of semiconductor material is subsequently grown on the second layer in the same manner as the first layer, i.e. by repeating the steps of patterning, etching and surface planarization. In contrast, embodiments of the present invention provide a fabrication technique that has two stages: a growth stage, where a layer arrangement is formed (by forming the layer arrangement prior to removing at least one portion of a second layer of the layer arrangement and removing a first layer of the layer arrangement); and a lattice formation stage (by removing at least one portion of the second layer and removing the first layer), where the layer arrangement is processed. Thus in embodiments of the present invention, formation of the lattice arrangement, which provides a photonic bandgap function, occurs in a single stage of the photonic crystal structure fabrication process. On the other hand, in the repeated etch-regrowth method -mentioned above, formation of the lattice arrangement involves repeatedly growing and processing each layer individually, a tedious process. Accordingly, one effect of embodiments of the present invention is that a simple and effective approach is provided to fabricate 3D photonic crystals in semiconductor materials.

In the context of the present invention, the term “photonic crystals” means a structure having a lattice arrangement that provides a photonic bandgap, i.e. a region in energy-momentum space wherein propagating photon modes do not exist. The photonic crystals may exhibit a bandgap along some directions or a bandgap along all directions.

The term “layer arrangement” means a structure having two or more layers having a specific spatial layout, i.e. being positioned relative to each other or to other layers. Each layer is preferably, although not limited, to being a flat plane of a semiconductor material. Each layer may be composed of materials which exhibit spatial variation of physical properties, composition, or other tangible characteristics, where that spatial variation produces useful bulk properties to the layer arrangement composition, and the spatial variation can be subdivided into a stack of structured layers, which are assembled atop one another with appropriate alignment between the various structured layers. An individual structured layer can exhibit one-, two-, or three-dimensional variation of physical properties, so long as the surfaces of the layers are substantially flat. Each of the layers in the layer arrangement is arbitrarily termed as a “first layer” and a “second layer”, wherein a group having a first layer and a second layer may form a partial layer arrangement.

The partial layer arrangements are arbitrarily termed a “first partial layer arrangement” and a “second partial layer arrangement”. The layer arrangement preferably includes two immediately adjacent partial layer arrangements, wherein the partial layer arrangement located further away from a support substrate surface is referred to as the “second partial layer arrangement”, while the other partial layer arrangement located nearer to the support substrate surface is referred to as the “first partial layer arrangement”, so that the second partial layer arrangement is disposed over the first partial layer arrangement. Alternatively, the first partial layer arrangement and the second partial layer arrangement may have one or more partial layer arrangements between them, i.e. the first partial layer arrangement and the second partial layer arrangement are not immediately adjacent to each other.

A first partial layer arrangement preferably includes two immediately adjacent layers, wherein the layer located further away from a support substrate surface is referred to as the second layer, while the other layer located nearer to the support substrate surface is referred to as the first layer, so that the second layer is disposed over the first layer. Similarly, a second partial layer arrangement preferably includes two immediately adjacent layers within the layer arrangement, wherein the layer further away from a support substrate surface is referred to as the second layer and the other layer referred to as the first layer, so that the second layer is disposed over the first layer. Alternatively, each of the first and second partial layer arrangements may group two selected layers having one or more layers between them, i.e. the two selected layers are not immediately adjacent to each other.

The material of the second layer has a different etching characteristic than the material of the first layer. In embodiments of the invention, their different etching characteristics may be achieved by having the first layer and the second layer made of different materials.

The term “support substrate” is meant to be understood in the context of semiconductor technology, i.e. “substrate” refers to bulk semiconductor material forming a base material for fabricating electronics or optoelectronics thereon or therein or for growing further layers of semiconductor material thereon.

In embodiments of the present invention, removing the at least one portion of the second layer may mean that within an optically active—region of the layer arrangement, the remaining second layer has gaps/openings present.—There may an equal interval between any two gaps of the second layer to form a periodic gap arrangement, or the intervals between any two gaps may not be equal. Removing the first layer may mean that the portion of the first layer within an optically active o region of the layer arrangement is completely removed, thereby making the first layer a sacrificial layer of the layer arrangement. However, a portion of the first layer may still remain as a spacer between adjacent second layers, so that the second—layers form an overhanging or suspended structure within the layer arrangement.—The result of removing the first layer and removing the at least one portion of the second layer is a lattice arrangement that provides a photonic bandgap function.

In embodiments of the present invention, forming the layer arrangement on the support substrate occurs prior to removing the at least one portion of the second layer and the first layer. Thus, forming the layer arrangement is the first step in the photonic crystal fabrication sequence. In one embodiment of the invention, the photonic crystal fabrication sequence has removing the at least one portion of the second layer as the second step and removing the first layer as the third step. In another embodiment of the invention, the photonic crystal fabrication sequence has removing the first layer as the second step and removing the at least one portion of the second layer as the third step.

In embodiments of the present invention, a mask may be deposited over the layer arrangement formed on the support substrate. The mask may be disposed on the second layer of the second partial layer arrangement and a pattern developed on the mask. The patterned mask facilitates removal of the at least one portion of the second layer. In the context of the present invention, the term “pattern” means to form a desired structure on the mask, through the removal of undesired portions of the mask. The patterned mask protects selected portions of the layer arrangement that are aligned to the patterned mask. The patterned mask thereby acts as a mold through which the pattern on the mask is replicated in selected layers of the layer arrangement through a controlled process that only removes undesired portions of the layer arrangement.

In embodiments of the present invention, the mask is—disposed after forming the layer arrangement. The patterned mask may be removed after the photonic crystals are formed.

In embodiments of the present invention, removing the at least one portion of the second layer occurs before removing the first layer. Thus, the photonic crystal fabrication sequence has forming the layer arrangement on the support substrate as the first step, removing the at least one portion of the second layer as the second step and removing the first layer as the third step.

On the other hand, in other embodiments of the present invention, removing the first layer occurs before removing the at least one portion of the second layer. Thus, the photonic crystal fabrication sequence has forming the layer arrangement on the support substrate as the first step, removing the first layer as the second step and removing the at least one portion of the second layer as the third step. Removing the first layer may include removing the first layer of the first partial layer arrangement and the first layer of the second partial layer arrangement in a single step, thereby providing the advantage of removing sacrificial layers of the layer arrangement in a single operation. A trench extending through the layer arrangement to a surface of the support substrate may be formed, the trench facilitating removing the first layer in a direction perpendicular to the direction the trench is formed. In the context of the present invention, the term “trench” may mean an opening extending through all layers of the layer arrangement to expose a surface of the support substrate. The term “perpendicular”, in the context of removing the first layer, may include a lateral direction, which is along the first layer and may be parallel to a surface of the support substrate. Forming the trench may occur after forming the layer arrangement. Thus, the trench may be formed before removing the at least one portion of the second layer and removing the first layer.

In embodiments of the present invention, the pattern on the mask may be developed after removing the first layer. On the other hand, in other embodiments of the present invention, developing a pattern on the mask occurs before removing the at least one portion of the second layer and removing the first layer.

In embodiments of the present invention, removing of the at least one portion of the second layer and removing of the first layer is performed such that a gap exists between adjacent remaining portions of the second layer. In the context of the present invention, the term “gap” may mean a region of space that surrounds a remaining portion of each second layer. The region of space may be a vacuum or be filled with air, a liquid or a solidified liquid.

In embodiments of the present invention, the layer arrangement includes a plurality of the first partial layer arrangement and a plurality of the second partial layer arrangement. Removing of the at least one portion of the second layer and removing of the first layer are reiterated on both the plurality of the first partial layer arrangement and the plurality of the second partial layer arrangement. In the context of the present invention, the term “reiterated” may mean the removal is done in repetitive identical sequences. One sequence may be first removing the at least one portion of the second layer, followed by removing the first layer. Another sequence may be first removing the first layer, followed by removing the at least one portion of the second layer. A further sequence may be removing the first layer of the first partial layer arrangement and the first layer of the second partial layer arrangement in a single step, followed by removing the at least one portion of the second layer of the second partial layer arrangement and subsequently removing the at least one portion of the second layer of the first partial layer arrangement.

In embodiments of the present invention, removing of the at least one portion of the second layer and removing of the first layer is performed by any one of the following procedures: etching or ion milling. The etching may either be a dry etch or a wet etch. Removing of the at least one portion of the second layer may be also be performed by any one of the procedures of plasma etching, focused ion beam etching, or ion milling. Removing of the first layer may be performed by chemical etching.

In embodiments of the present invention, the thicknesses of the first layer and the second layer may be the same or different.

In embodiments of the present invention, within each partial layer arrangement, the first layer and the second layer may be in contact with each other. The first layer of the first partial layer arrangement may use the same material as the first layer of the second partial layer arrangement. The second layer of the first partial layer arrangement may use the same or different material as the second layer of the second partial layer arrangement.

In embodiments of the present invention, the first layer may include InP, GaAs or Si. The second layer may include InGaAsP, InGaAlAs, AlGaAs, InGaAs, InGaAsN, SiC or SiGe. In other embodiments of the present invention, the first layer may include any one of InGaAsP, InGaAlAs, AlGaAs, InGaAs, InGaNAs, SiC or SiGe. The second layer may include any one of InP, GaAs, or Si.

In embodiments of the present invention, the patterned layer may include any one or more of photoresist, silicon dioxide, silicon nitride, metal or dielectric material.

In embodiments of the present invention, removing of the at least one portion of the second layer is such that, along an axis perpendicular to a surface of the support substrate, at least one location where the portion of a second layer is removed is aligned with a remaining portion of an adjacent second layer. Thus, a portion of a light beam propagating within the layer arrangement and along a direction that is perpendicular to a surface of the support substrate will only intersect second layer material (i.e. the second layer that remains after removal of at least one portion) that is along the path of the light beam. The light beam will be modulated when it intersects with the second layer. There may be planes where the portion of the light beam will pass through the removed portion of the respective second layer and therefore experience no modulation.

In embodiments of the present invention, the support substrate may be tilted, for example, during dry etching or ion milling to remove the at least one portion of the second layer. The angle of tilt may be around 20° to 70°.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A is a schematic view of optical structures having 1D, 2D and 3D configurations.

FIG. 1B shows a flow chart illustrating a method, according to one embodiment of the present invention, of forming photonic crystals.

FIGS. 2A to 2H illustrate manufacturing of photonic crystals in accordance to one embodiment of the invention.

FIGS. 3A to 3C are SEM pictures of a multilayer structure after selective lateral wet etching.

FIGS. 4A and 4B are SEM pictures of 3D photonic crystal structures created in accordance with embodiments of the invention.

FIG. 5 shows a cross-sectional view of a 3D lattice structure made using a tilt plasma etching method.

FIG. 6 shows cross-sectional views of a 3D photonic crystal formed by tilt angle plasma etch and a 3D photonic crystal formed by normal plasma etch.

FIGS. 7A to 7D illustrate manufacturing of photonic crystals in accordance to one embodiment of the invention. FIGS. 8 and 9 each show a SEM picture of a 3D photonic crystal sample after FIB etch.

FIGS. 10A to 10F illustrate manufacturing of photonic crystals in accordance to one embodiment of the invention.

FIG. 11 shows a cross-sectional view of a 3D photonic crystal formed in accordance to one embodiment of the invention.

FIG. 12 shows a table summarising InGaAsP and InP thicknesses for a 3D photonic crystal.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

According to various embodiments of the invention, methods are provided to easily, simply and effectively fabricate 3D photonic crystals in single crystal semiconductor materials, including Si and III-V compound semiconductor based materials.

Firstly, a multi-layer material or layer arrangement is grown one layer at a time to ensure good crystal quality. For example, they can be grown by epitaxy technologies, such as metal organic chemical vapor deposition (MOCVD) and molecular beam epitaxy (MBE) for materials like GaAs/AlGaAs, GaAs/InGaAs, InP/InGaAsP and Si/SiGe etc. Both the composition and thickness of each layer can be easily tuned and precisely controlled at atomic level during the epitaxy.

Next, sacrificial epitaxy layers within the layer arrangement are removed by, for example, selective wet-etch, so that regions of the layer arrangement adjacent to where the sacrificial epitaxy layers are removed form overhanging layers. For example, an InGaAsP overhanging structure may be formed by removing InP layers. The sacrificial epitaxy layers may be removed either before 3D photonic crystal pattern formation by using deep trenches and lateral selective etching, in accordance with an embodiment of the invention; or can be done after exposure of each sacrificial layer during transfer of 2D hole patterns into the layer arrangement, in accordance with another embodiment of the invention using a layer-by-layer etch approach. According to various embodiments of the invention, the effective semiconductor material thickness in a plasma etch may be equivalent to only one layer of InGaAsP, leading to a reduction of thickness from, for example ˜5000 nm to ˜200 nm.

By removing the sacrificial semiconductor layer, the refractive index contrast in a vertical direction changes from, e.g. for InP and InGaAsP: 3.2 and 3.45, to air and InGaAsP of 1 and 3.45, which may be big enough for a complete photonic bandgap.

In a planar direction, a nano-lithography method and anisotropic dry-etching may be used to define the period and lattice-size. 2D photonic crystal patterns may be created by various techniques, such as e-beam lithography, nano-imprinting, laser holographic lithography, etc. The 2D photonic crystal pattern is replicated to the overhanging layers below through, for example, anisotropic dry etching.

The lattice structure of the photonic crystal may be varied by controlling the plasma etching angle, e.g. tilted plasma etching together with the 2D photonic crystal pattern. Defects can also be introduced into the photonic crystal structure by, for example, changing the material composition and layer thickness in a 1D multi-layer structure, as well as by changing the patterns in the 2D photonic crystal structure.

In a vertical direction, materials, period and thickness are defined using, for example, an epitaxy method. In a planar direction, the period and the lattice is defined using, for example, a 2D planar lithography method. As a result, forming photonic crystals in accordance with embodiments of the invention do not require laborious and time consuming arrangement of a 3 dimensional lattice. Hence, it is simple.

Various embodiments of the invention has the advantage of producing uniform patterns in all semiconductor layers in all depths, in contrast with existing methods, especially for 3D photonic crystals which are to be invisible to light having frequency near the infra-red wavelength range.

Various embodiments of the invention produce a photonic crystal structure with a high refractive index contrast that is able to form a complete photonic bandgap.

Various embodiments of the invention can change 3D photonic crystal properties by introducing defects through varying a 2D pattern, varying the layer arrangement growth or changing a plasma etching angle.

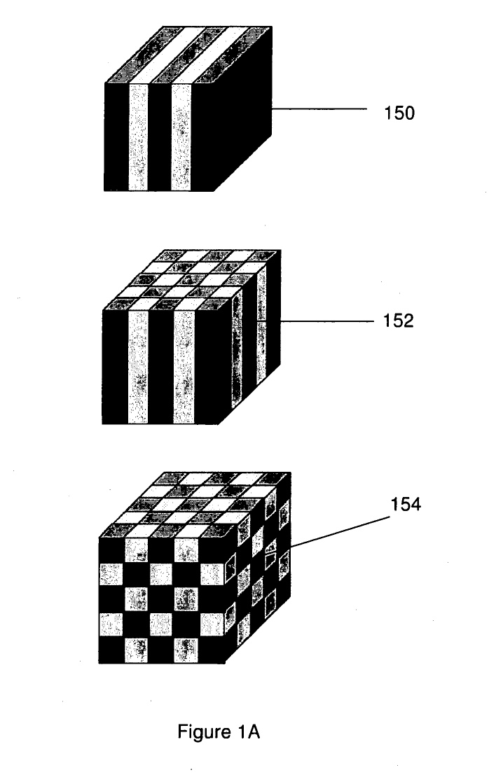

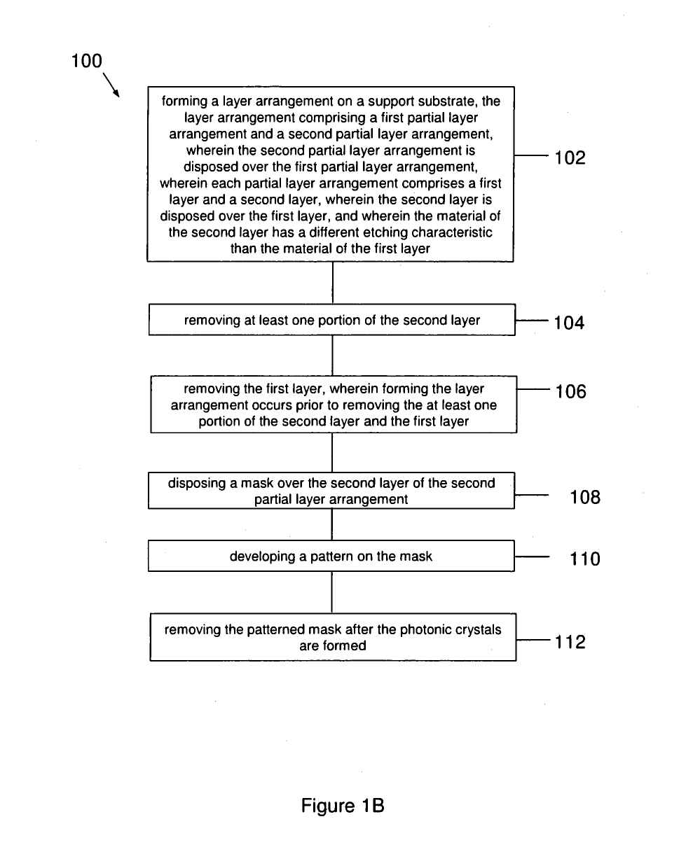

FIG. 1A is a schematic view of optical structures 150, 152 and 154 having 1D (one-dimensional), 2D (two-dimensional) and 3D (three-dimensional) configurations respectively.

With reference to optical structure 150, in the context of the present invention, the term “1D” may mean an optical structure with a periodic pattern, providing a photonic bandgap function, repeating in one direction.

With reference to optical structure 152, in the context of the present invention, the term “2D” may mean an optical structure with a periodic pattern, providing a photonic bandgap function, repeating in two directions.

With reference to optical structure 154, in the context of the present invention, the term “3D” may mean an optical structure with a periodic pattern, providing a photonic bandgap function, repeating in three directions. Further, the term “3D” may include any structural configuration which extends beyond a single, two-dimensional layer. Accordingly, “3D” covers configurations which are unordered or randomly ordered in three dimensions; that is, the configurations embraced by these terms do not need to be regular or periodic in any way. However, “3D” also covers ordered configurations, including configurations which exhibit either two-dimensional order or three-dimensional order. A 3D pattern which exhibits two-dimensional order has regularity or periodicity in two dimensions but not necessarily in the third dimension.

FIG. 1B shows a flow chart 100 illustrating a method, according to one embodiment of the present invention, of forming 3D photonic crystals. The method provides a technique to fabricate photonic crystals or photonic bandgap structures in semiconductor materials, such as InGaAsP/InP, GaAs/AlGaAs, or SiGe/Si.

At 102, a layer arrangement is formed on a support substrate. The layer arrangement includes a first partial layer arrangement and a second partial layer arrangement, wherein the second partial layer arrangement is disposed over the first partial layer arrangement, wherein each partial layer arrangement comprises a first layer and a second layer, wherein the second layer is disposed over the first layer, and wherein the material of the second layer has a different etching characteristic than the material of the first layer. The method further includes removing at least one portion of the second layer and removing the first layer, wherein forming the layer arrangement occurs prior to removing the at least one portion of the second layer and the first layer.

At 104, at least one portion of the second layer is removed, while at 106, the first layer is removed. Referring to 102, forming the layer arrangement occurs prior to removing the at least one portion of the second layer (at 104) and removing the first layer (at 106).

At 108, a mask is disposed on the second layer of the second partial layer arrangement. At 110, a pattern is developed on the mask. The patterned mask facilitates removal of the at least one portion of the second layer. At 112, the patterned mask is removed after the photonic crystals are formed.

In one embodiment of the invention, the flow chart 100 may be implemented as follows:
I. growing a multi-layer structure (or layer arrangement) on a semiconductor substrate or support substrate; each layer within the multi-layer structure may include a different material and be of a certain thickness according to design, e.g. epitaxy multiple InGaAsP/InP layers on InP substrate using MOCVD;
II. forming a hard mask for deep trench etching; the hard mask may be made of silicon dioxide (SiO₂), SiₓN_{y} or metal deposited by plasma enhanced chemical vapor deposition (PECVD), physical vapor deposition (PVD) or electron beam evaporation (e-beam evaporation); the trench pattern on the hard mask may be formed by photolithography patterning and plasma etching, e.g. reactive ion etching (RIE), inductively coupled plasma (ICP) etching; the trench pattern may be aligned to certain crystalline direction, i.e. along [0, 1, 0] or [0, 0, 1] direction if the support substrate is in [1, 0, 0] direction;
III. plasma etching the multi-layer structure to the semiconductor substrate to define the trenches;
IV. depositing a polymethyl methacrylate (PMMA) layer on the multi-layer structure, forming the 2D photonic crystal nano-patterns in the PMMA layer using e-beam lithography, followed by transferring the 2D photonic crystal nano-patterns onto the hard mask, e.g., silicon dioxide layer by dry etching, removing the PMMA layer;
V. selective wet chemical etching in lateral direction to remove the sacrificial layers, e.g. remove InP using HCl:H₃PO₄ 1:2 solution and leave the InGaAsP layers;
VI. plasma etching the InGaAsP layers to transfer the 2D photonic crystal pattern to the respective InGaAsP layers to form the 3D photonic crystals.

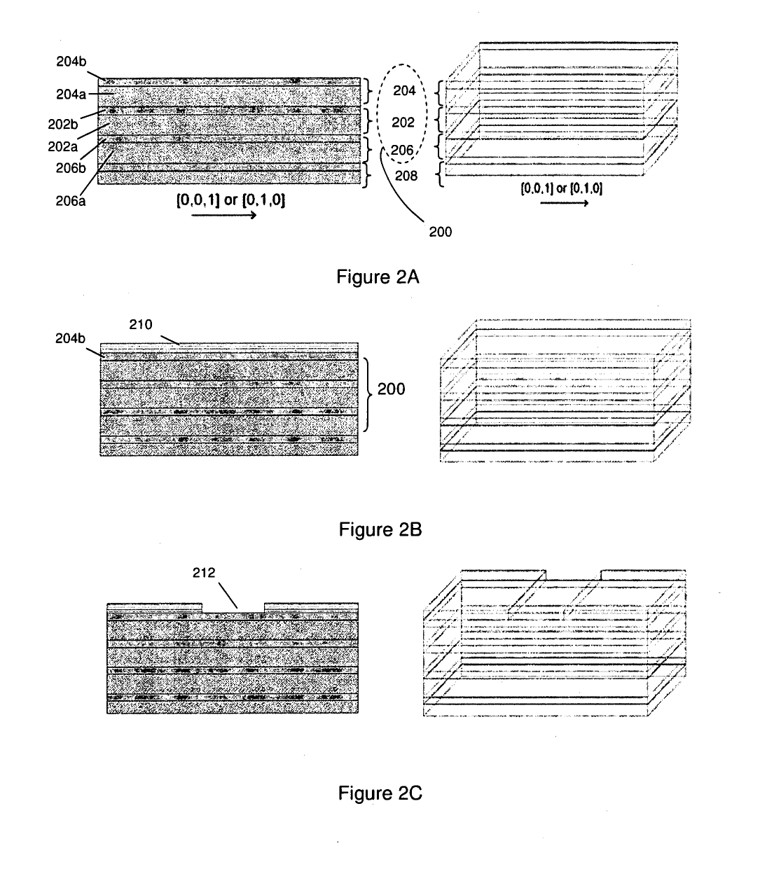

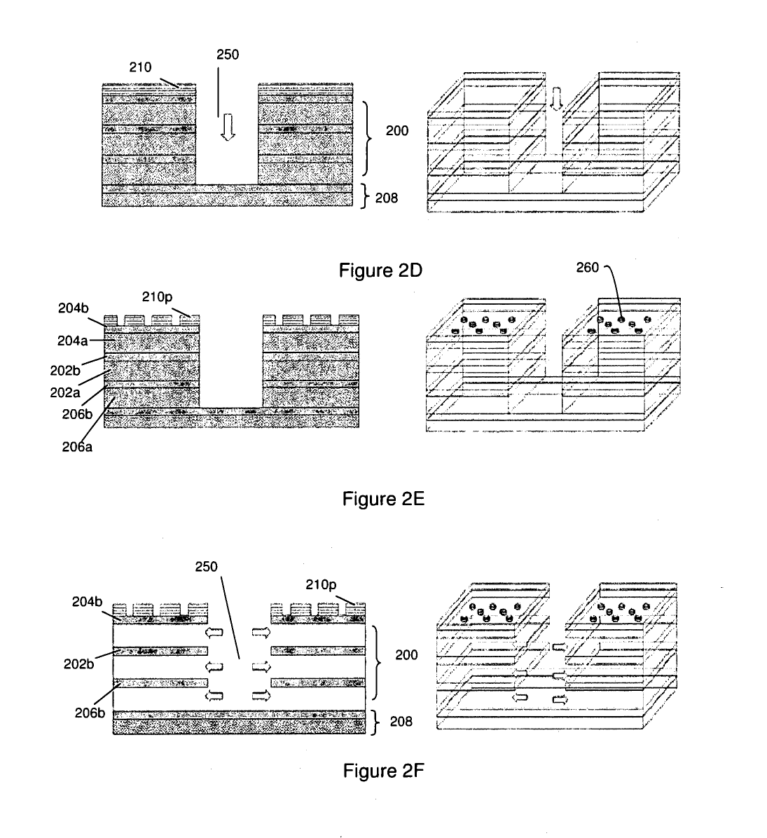

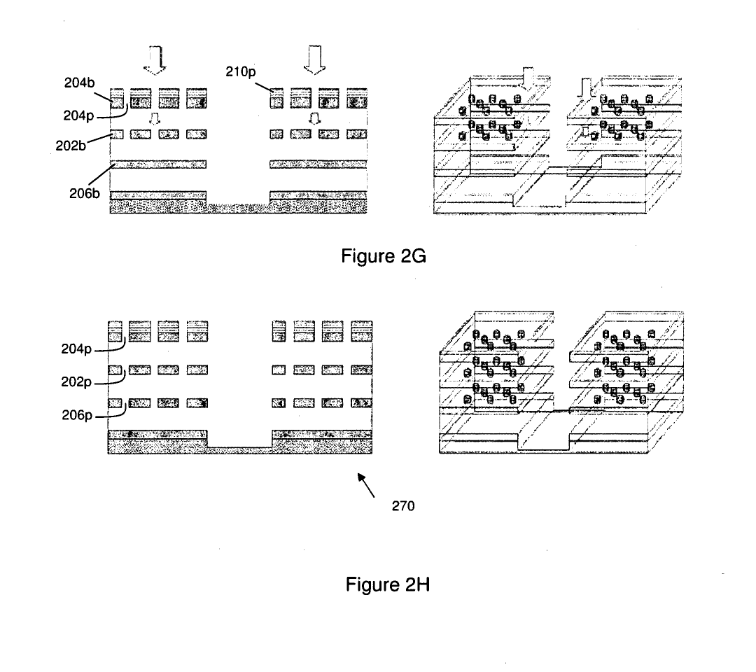

FIGS. 2A to 2H illustrate an implementation of the method of FIG. 1B, i.e. manufacturing of photonic crystals in accordance to one embodiment of the invention. Each of FIGS. 2A to 2H shows both a cross-sectional view and a 3D view of the fabrication process. For the purpose of illustration, only three partial layer arrangements 202, 204, 206 are shown, each partial layer arrangement having a pair of layers.

In FIG. 2A, a layer arrangement 200 is formed on a [1, 0, 0] support substrate 208. In the embodiment shown in FIG. 2A, an InP substrate may be used

The layer arrangement 200 includes a first partial layer arrangement 202, a second partial layer arrangement 204 and a third partial layer arrangement 206. The second partial layer arrangement 204 is disposed over the first partial layer arrangement 202. Each partial layer arrangement (202, 204, 206) includes a first layer (denoted 202a, 204a and 206a for the first partial layer arrangement 202, the second partial layer arrangement 204 and the third partial layer arrangement 206 respectively) and a second layer (denoted 202b, 204b and 206b for the first partial layer arrangement 202, the second partial layer arrangement 204 and the third partial layer arrangement 206 respectively), wherein the second layer (202b, 204b and 206b) is disposed over the first layer (202a, 204a and 206a). The material of the second layer (202b, 204b and 206b) has a different etching characteristic than the material of the first layer (202a, 204a and 206a). In the embodiment shown in FIG. 2A, InP may be used for the first layer (202a, 204a and 206a), while InGaAsP may be used for the second layer (202b, 204b and 206b) so that the partial layer arrangements (202, 204 and 206) form InGaAsP/InP-stack layers. Forming the layer arrangement 100 occurs prior to removing at least one portion of the second layer (202b, 204b and 206b) and removing the first layer.

In FIG. 2B, a mask 210 is disposed after forming the layer arrangement 200. The mask 210 is deposited over the second layer 204b of the second partial layer arrangement 204. In the embodiment shown in FIG. 2B, silicon dioxide may be used for the mask 210.

In FIG. 2C, a photoresist (not shown) is deposited and an opening 212 is patterned using a standard photolithography process. It is preferable to align the opening 212 as parallel as possible to a [0, 0, 1] or [0, 1, 0] direction on the [1, 0, 0] support substrate 208. The opening 212 will subsequently be extended to create a trench 250 (see FIG. 2D) in the layer arrangement 200 long enough relative to the amount of lateral etching (see FIG. 2F) desired. Etching of the mask 210 is then performed to define the opening 212, as shown in FIG. 1C. For example, when silicon dioxide is used for the mask 210, the silicon dioxide may be dry-etched by reactive ion etching (RIE) using CHF₃ and Ar plasma. The photoresist is then removed using Acetone for example.

In FIG. 2D, a dry etch is performed to define a deep trench 250 extending through the layer arrangement 200 to a surface of a second layer of a partial arrangement adjacent to the support substrate 208. For example, inductive coupled plasma (ICP) system using BCl₃/Cl₂/Ar gas may be used to perform the dry etch. With reference to FIG. 2F, the trench 250 facilitates removing the first layer (202a, 204a and 206a) in a direction perpendicular to the direction the trench 250 is formed. Since FIG. 2D occurs after FIG. 2A, forming the trench 250 occurs after forming the layer arrangement 200.

After the ICP etch, a layer of polymethyl methacrylate (PMMA, not shown) is coated on the mask 210. Electron-beam lithography is then used to create a 2D photonic crystal pattern (a periodic hole-array arranged in a hexagonal pattern) on the PMMA layer. The size and the spacing between each hole (or period) within the hole-array may be designed to have a photonic bandgap for wavelength at about 1.55 um. Other nanolithography method, such as laser-holographic method, may equally be used to create the 2D nano patterns. Next, dry etching of the mask 210 may be performed to transfer the 2D photonic crystal pattern on the mask 210, thereby developing a pattern on the mask 210 and forming a patterned mask 210p, as shown in FIG. 2E, with the 2D photonic crystal pattern 260. Developing a pattern on the mask 210 occurs before removing at least one portion of the second layer (202b, 204b and 206b) and removing the first layer (202a, 204a and 206a). The PMMA layer may be removed after the mask 210 2D hole-array etch.

In FIG. 2F, the layer arrangement 200 on the support substrate 208 may be dipped into a wet etchant to create second layers (202b, 204b and 206b) that are overhanging by removing the first layers (202a, 204a and 206a, see FIG. 2E) through a selective wet-etch in the lateral direction. For example, HCl:H₃PO₄ (mixing ratio=1:2) may be used for the selective removal of InP first layers (202a, 204a and 206a) with an etching selectivity to InGaAsP second layers (202b, 204b and 206b) better than 1:100. The lateral direction etch is facilitated by the trench 250 allowing removal of the first layers (202a, 204a and 206a, see FIG. 2E) in a direction perpendicular to the direction the trench 250 is formed. In the embodiment shown in FIG. 2F, the first layer 202a of the first partial layer arrangement 202, the first layer 204a of the second partial layer arrangement 204 and the first layer 206a of the third partial layer arrangement 206 are removed in a single step.

In FIG. 2G, a second dry etch process, using for example plasma, may be performed to remove at least one portion (202p, 204p and 206p, see FIG. 2H) of each of the second layers (202b, 204b and 206b), which are overhanging, through the patterned mask 210p having the 2D photonic crystal pattern. Thus, the patterned mask 210p facilitates removal of at least one portion of a second layer.

It has been found to be difficult to etch a hole-array with a hole diameter of about 160 nm to a depth of about several microns, e.g. 3 um, in solid semiconductor material, while keeping the original profile of the pattern along the etch path. In the current invention, by removing the first layers (202a, 204a and 206a) before removing the at least one portion (202p, 204p and 206p) of the second layers (202b, 204b and 206b), the effective etch thickness may be reduced to that of one second layer, which may be about 160 nm thick. The etchant will encounter an air gap after penetration of every 160 nm second layer. As a result, the 2D photonic crystal pattern 260 on the patterned mask 210p will be replicated into the second layer 204b below the patterned mask 210p and be replicated to all other second layers (202b and 206b), as shown in FIG. 2G.

Through one ICP etch, a 3D photonic crystal 270, e.g. orthorhombic lattice structure, may be finally formed, as shown in FIG. 2H.

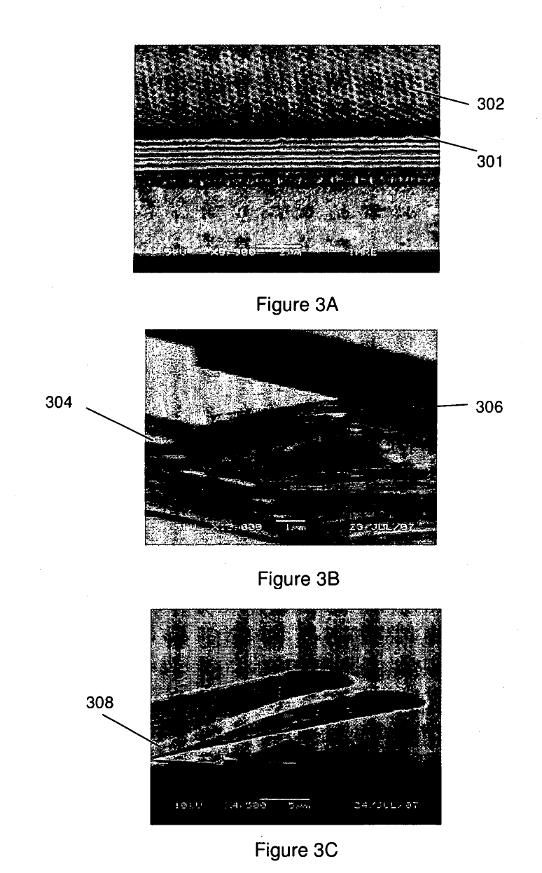

FIGS. 3A to 3C are SEM pictures of a multilayer structure after selective lateral wet etching. FIG. 3A shows a structure where the top layer 301 is a SiO₂ mask with 2D photonic crystal hole patterns 302. FIGS. 3B and 3C both respectively show overhanging structures 306 and 308 formed, where the nano-patterning step is skipped (i.e. without using a SiO₂ mask layer to form 2D photonic crystal hole patterns). In FIG. 3B, the duration of the selective wet-etch is not long enough to etch through InP layers 302. In FIG. 3C, a selective wet-etch process has completely removed InP layers of a ridge structure. The multilayer is broken due to cleaving.

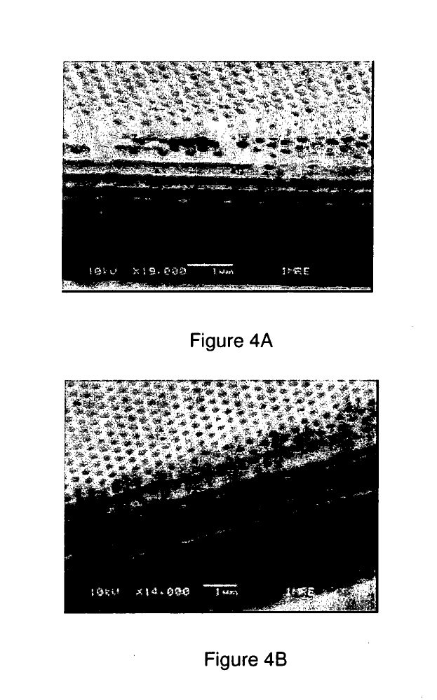

FIGS. 4A and 4B are SEM pictures of 3D photonic crystal structures created in accordance with embodiments of the invention. In both FIGS. 4A and 4B, four layers of 2D photonic crystals are visible.

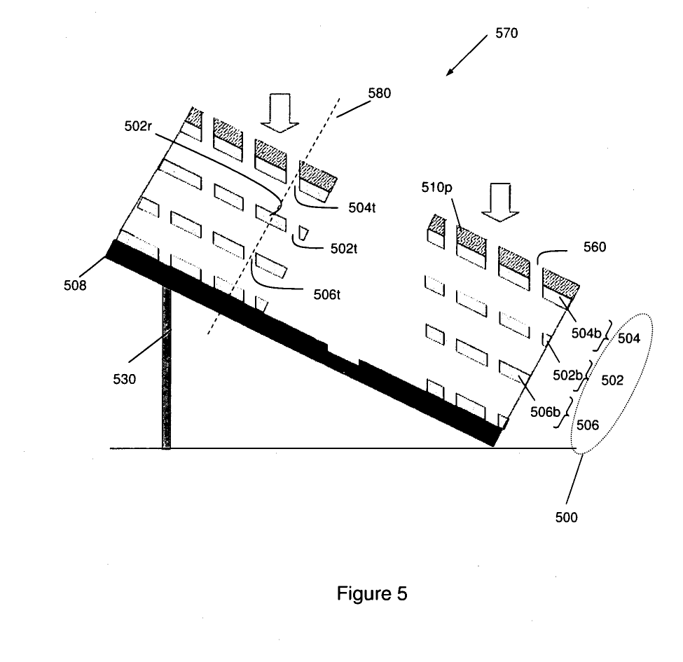

In accordance to one embodiment of the invention, a method to fabricate a different 3D lattice structure is provided. A cross-sectional view of a 3D photonic crystal 570 having the different 3D lattice structure, made using a tilt plasma etching method, is shown in FIG. 5.

The 3D photonic crystal 570 has a layer arrangement 500 having a plurality of second layers (502b, 504b and 506b), the layer arrangement 500 formed on a support substrate 508. Each of the second layers (502b, 504b and 506b) has at least one portion (502t, 504t and 506t) removed respectively. A patterned mask 510p is disposed above the second layer 504b.

One possible way to produce the 3D lattice structure 500 is through performing the fabrication method described with reference to FIGS. 2A to 2F above and is therefore not further elaborated. Comparing FIG. 5 with FIG. 2F: second layers (502b, 504b and 506b) correspond to second layers (202b, 204b and 206b) respectively; patterned mask 510p corresponds to patterned mask 210p; and substrate 508 corresponds to substrate 208. It will thus be appreciated that in FIG. 5, the second layer 502b belongs to a first partial layer arrangement 502, the second layer 504b belongs to a second partial layer arrangement 504 and the third layer 506b belongs to a third partial layer arrangement 506. Within each partial layer arrangement (502, 504 and 506), a respective first layer (not shown) has already been removed.

In FIG. 5, instead of putting the support substrate 508 on a flat sample holder, the support substrate 508 is tilted before removing at least one portion (502t, 504t and 506t) of the second layer (502b, 504b and 506b). The support substrate 508 is tilted to a desired angle, such as around 20° to 70°, using a piece of semiconductor wafer bar 530 or any other suitable support member that is fixed to one side of the support substrate 530, or by putting the support substrate 530 into a tilted mold (not shown). A plasma etch will transfer a 2D photonic crystal pattern 560 from the patterned mask 510p by removing, at an angle, the at least one portion (502t, 504t and 506t) of the second layers (502b, 504b and 506b), which are overhanging. The lattice structure of the 3D photonic crystal 570 created through tilt etch is different from the 3D photonic crystal 270 (see FIG. 2H) created through vertical etch.

For the 3D photonic crystal 570 created through tilt etch, removing of the at least one portion (502t, 504t and 506t) of the second layer (502b, 504b and 506b) is such that, along an axis 580 perpendicular to a surface of the support substrate 508, at least one location where the portion (e.g.: 504t) of a second layer (e.g.: 504) is removed is aligned with a remaining portion (e.g.: 502r) of an adjacent second layer (e.g.: 502). Thus, a portion of a light beam propagating within the layer arrangement 500 and along a direction that is perpendicular to a surface of the support substrate 508 will only intersect second layer material (i.e. the second layer [502b, 504b and 506b], which remains after removal of selected portions [502t, 504t and 506t]), along the path of the light beam. The light beam will be modulated when it intersects with the second layer (502b, 504b and 506b). There may be planes where the portion of the light beam will pass through removed portions (502t, 504t and 506t) of the respective second layer (502b, 504b and 506b) and therefore experience no modulation.

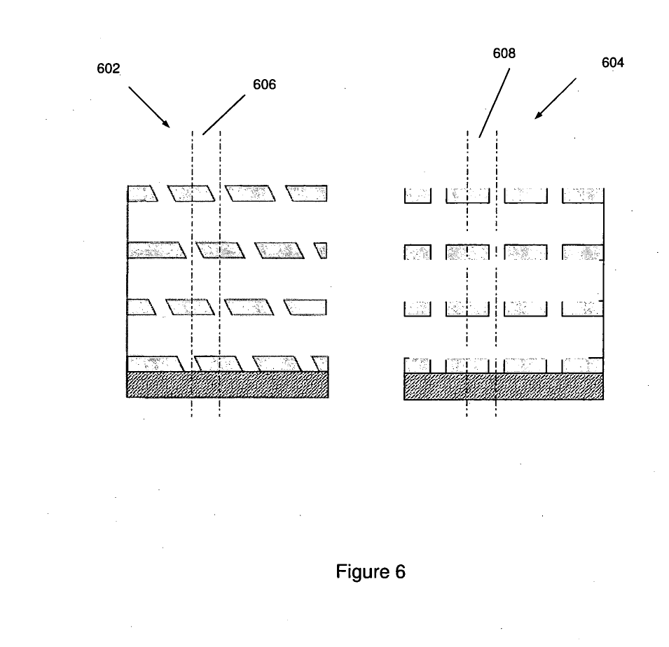

FIG. 6 shows cross-sectional views of a 3D photonic crystal 602 formed by tilt angle plasma etch and a 3D photonic crystal 604 formed by normal plasma etch. Light 606 and 608 may experience a different lattice structure when propagating or shining in the vertical direction.

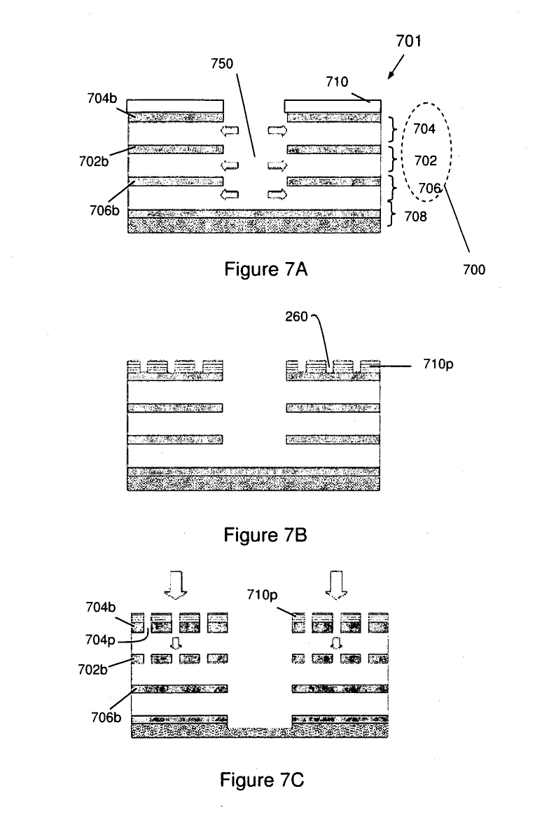

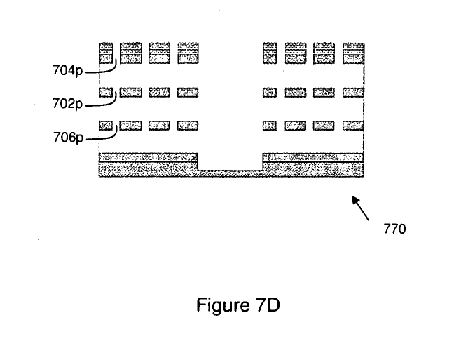

FIGS. 7A to 7D illustrate an implementation of the method of FIG. 1B, i.e. manufacturing of photonic crystals, in accordance to one embodiment of the invention. Each of FIGS. 7A to 7D shows a cross-sectional view of the fabrication process.

FIG. 7A shows a structure 701 with a layer arrangement 700 having a plurality of second layers (702b, 704b and 706b), the layer arrangement 700 formed on a support substrate 708. A mask 710 is disposed above the second layer 704b.

One possible way to produce the structure 701 is through performing the fabrication method described with reference to FIGS. 2A to 2D above and is therefore not further elaborated. Comparing FIG. 7A with FIG. 2D: second layers (702b, 704b and 706b) correspond to second layers (202b, 204b and 206b) respectively; mask 510 corresponds to mask 210; and substrate 708 corresponds to substrate 208. It will thus be appreciated that in FIG. 7A, the second layer 702b belongs to a first partial layer arrangement 702, the second layer 704b belongs to a second partial layer arrangement 704 and the third layer 706b belongs to a third partial layer arrangement 706.

In FIG. 7A, a first layer (not shown) of each partial layer arrangement (702, 704 and 706) is removed by dipping the layer arrangement 700 on the support substrate 708 into a wet etchant. The removal of the first layers, through a selective wet-etch in the lateral direction, creates second layers (702b, 704b and 706b) that are overhanging. For example, HCl:H₃PO₄ (mixing ratio=1:2) may be used for the selective removal of InP first layers (not shown) with an etching selectivity to InGaAsP second layers (702b, 704b and 706b) better than 1:100. The lateral direction etch is facilitated by a trench 750 allowing removal of the first layers in a direction perpendicular to the direction the trench 750 is formed. In the embodiment shown in FIG. 7A, respective first layers of the partial layer arrangements (702, 704 and 706) are removed in a single step.

After removing the first layers, a layer of polymethyl methacrylate (PMMA, not shown) is coated on the mask 710. Electron-beam lithography is then used to create a 2D photonic crystal pattern (a periodic hole-array arranged in a hexagonal pattern) on the PMMA layer. The size and the spacing between each hole (or period) within the hole-array may be designed to have a photonic bandgap for wavelength at about 1.55 um. Other nanolithography method, such as laser-holographic method, may equally be used to create the 2D nano patterns. Next, dry etching of the mask 710 may be performed to transfer the 2D photonic crystal pattern on the mask 710, thereby forming a patterned mask 710p, as shown in FIG. 7B, with the 2D photonic crystal pattern 760. In contrast to FIG. 2E (where developing a pattern on the mask occurs before removing at least one portion of the second layer and removing the first layer), FIG. 7B has developing a pattern on the mask 710 occurring after removing the first layers. The PMMA layer may be removed after the mask 710 2D hole-array etch.

In FIG. 7C, a second dry etch process, using for example plasma, may be performed to remove at least one portion (702p, 704p and 706p, see FIG. 7D) of each of the second layers (702b, 704b and 706b), which are overhanging, through the patterned mask 710p having the 2D photonic crystal pattern 760. Thus, the patterned mask 710p facilitates removal of at least one portion of a second layer.

It has been found to be difficult to etch a hole-array with a hole diameter of about 160 nm to a depth of about several microns, e.g. 3 um, in solid semiconductor material, while keeping the original profile of the pattern along the etch path. In the current invention, by removing the first layers (not shown) before removing the at least one portion (702p, 704p and 706p) of the second layers (702b, 704b and 706b), the effective etch thickness may be reduced to that of one second layer, which may be about 160 nm thick. The etchant will encounter an air gap after penetration of every 160 nm second layer. As a result, the 2D photonic crystal pattern 760 on the patterned mask 710p will be replicated into the second layer 704b below the patterned mask 710p and be replicated to all other second layers (702b and 706b), as shown in FIG. 7D.

Through one ICP etch, a 3D photonic crystal 770, e.g. orthorhombic lattice structure, may be finally formed, as shown in FIG. 7D.

Besides plasma dry etching, ion-milling method, such as focus ion beam (FIB), may also be used to fabricate 3D photonic crystals. FIB can be used to directly form the photonic crystal structure after removing the first layer, without nano-patterning 2D photonic crystal patterns. FIB may be used to cut or obtain a cross-section of the 3D photonic crystal structure to obtain a 3D view. FIGS. 8 and 9 each show a SEM picture of a 3D photonic crystal sample after FIB etch. From both figures, four different layers of 2D photonic crystals may be seen.

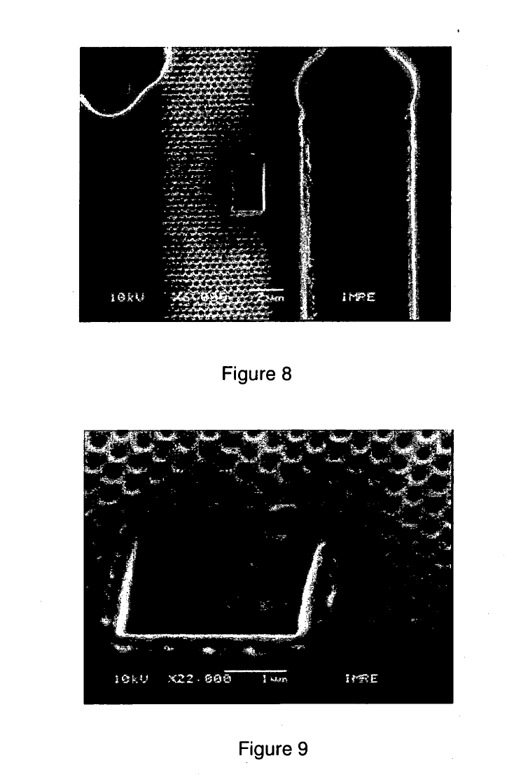

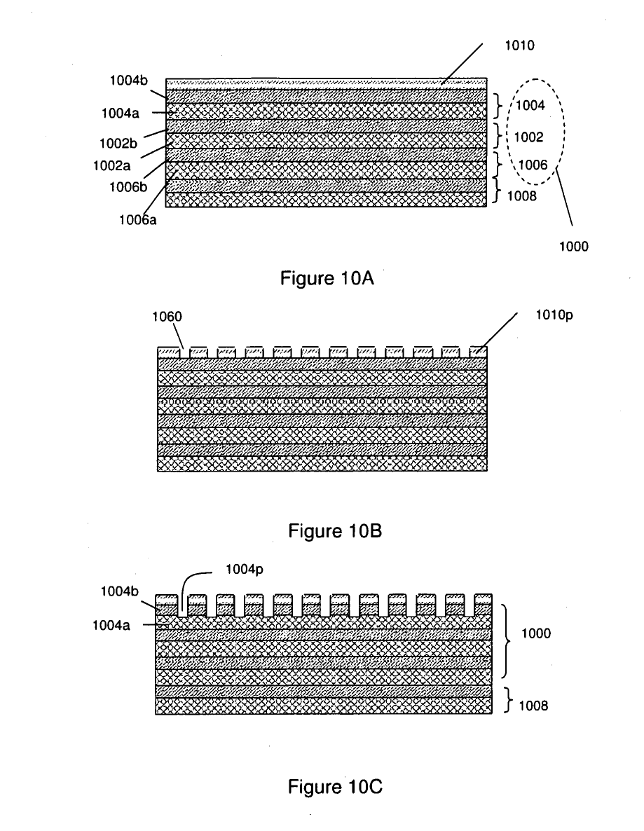

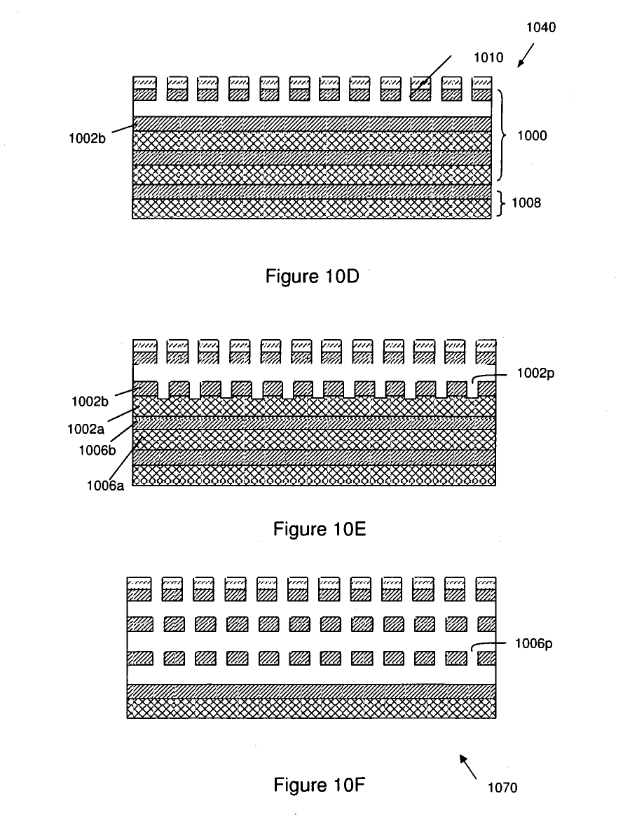

FIGS. 10A to 10F illustrate an implementation of the method of FIG. 1B, i.e. manufacturing of photonic crystals in accordance to one embodiment of the invention. Each of FIGS. 10A to 10F shows a cross-sectional view of the fabrication process.

In FIG. 10A, a layer arrangement 1000, used to fabricate a 3D photonic crystal is formed on a support substrate 1008. In the embodiment shown in FIG. 10A, an InP substrate may be used.

The layer arrangement 1000 includes a plurality of partial layer arrangements 1002, 1004 and 1006. When considering partial layer arrangements 1002 and 1004, the partial layer arrangement 1004 will be denoted as a second partial layer arrangement of the plurality of partial layer arrangements, while partial layer arrangement 1002 will be denoted as a first partial layer arrangement of the plurality of partial layer arrangements. Similarly, when considering partial layer arrangements 1002 and 1006, the partial layer arrangement 1002 will be denoted as a second partial layer arrangement of the plurality of partial layer arrangements, while partial layer arrangement 1006 will be denoted as a first partial layer arrangement of the plurality of partial layer arrangements. The following description in respect of FIGS. 10A to 10H will refer to partial layer arrangement 1004 as the second partial layer arrangement and partial layer arrangement 1002 as the first partial layer arrangement.

Accordingly, the layer arrangement 1000 has a plurality of first partial layer arrangements 1002 and a plurality of second partial layer arrangements 1004. A respective one of the plurality of second partial layer arrangements 1004 is disposed over a respective one of the plurality of first partial layer arrangements 1002. Each of the plurality of partial layer arrangements (1002, 1004 and 1006) includes a first layer (denoted 1002a, 1004a and 1006a for the first partial layer arrangement 1002, the second partial layer arrangement 1004 and the partial layer arrangement 1006 respectively) and a second layer (denoted 1002b, 1004b and 1006b for the first partial layer arrangement 1002, the second partial layer arrangement 1004 and the partial layer arrangement 1006 respectively), wherein the second layer (1002b, 1004b and 1006b) is disposed over the first layer (1002a, 1004a and 1006a). The material of the second layer (1002b, 1004b and 1006b) has a different etching characteristic than the material of the first layer (1002a, 1004a and 1006a). In the embodiment shown in FIG. 10A, InP may be used for the first layer (1002a, 1004a and 1006a), while InGaAsP may be used for the second layer (1002b, 1004b and 1006b) so that the partial layer arrangements (1002, 1004 and 1006) form InGaAsP/InP-stack layers. A mask 1010, made from dielectric material such as SiO₂ or SiN, is disposed after forming the layer arrangement 1000. Forming the layer arrangement 1000 occurs prior to removing at least one portion of the second layer (1002b, 1004b and 1006b) and removing the first layer (1002a, 1004a and 1006a). The mask 1010 is deposited over the second layer 1004b of the second partial layer arrangement 1004 furthest from the support substrate 1008.

In FIG. 10B, the mask 1010 is patterned with a 2D photonic crystal pattern 1060 and etched by RIE to form a patterned mask 1010p. Developing the pattern 1060 on the mask 1010 occurs before removing at least one portion of the second layer (1002b, 1004b and 1006b) and removing the first layer (1002a, 1004a and 1006a).

In FIG. 10C, a first plasma etch, like ICP, is used to transfer the 2D photonic crystal pattern 1060 from the patterned mask 1010p to the second layer 1004b, thereby removing at least one portion 1004p of the second layer 1004b. The plasma etch will etch through the second layer 1004b into the layer directly below, i.e. the first layer 1004a.

The layer arrangement 1000 on the support substrate 1008 will be put into a chemical solution, like HCl:H₂O or HCl:H₃PO₄, to etch away the exposed first layer 1004a. Thus, removing of the at least one portion 1004p of the second layer 1004b occurs before removing the first layer 1004a. In this manner, the first layer 1004a is removed as shown in FIG. 10D. Since hole size and space between holes are normally quite small for near IR wavelength, being in the range of hundred(s) nanometers, there may not be much concern of etch stop at certain crystalline directions.

The sample 1040 is rinsed and dried, put back into an etching chamber and plasma etch as described with reference to FIG. 10C is repeated to remove at least one portion 1002p of the second layer 1002b, as shown in FIG. 10E. Plasma etch to remove at least one portion (1006p, see FIG. 10F) of subsequent second layers (1006b, see FIG. 10F) and chemical etching (as described with reference to FIG. 10D) to remove first layers (1002a and 1006a) is repeated for the number of partial layer arrangements used. While FIGS. 10C to 10F show removal of the at least one portion (1002p, 1004p and 1006p) of the second layer (1002b, 1004b and 1006b) and removal of the first layer (1002a, 1004a and 1006a), it will be appreciated that the removal may be reiterated on both the plurality of the first partial layer arrangements and the plurality of the second partial layer arrangements present in the layer arrangement 1000.

In FIG. 10F, a 3D photonic crystal structure 1070 will be formed.

A variation of the as method described with reference to FIGS. 10A to 10F may be undertaken to form a different 3D lattice structure (not shown). From FIG. 10A, instead of putting the support substrate 1008 on a flat sample holder, the support substrate 1008 is tilted (not shown) before removing at least one portion (1002p, 1004p and 1006p) of the second layer (1002b, 1004b and 1006b). The support substrate 1008 is tilted to a desired angle, such as around 20° to 70°. Removal of the at least one portion (1002p, 1004p and 1006p) of the second layer (1002b, 1004b and 1006b) and removal of the first layer (1002a, 1004a and 1006a) will follow as described with reference to FIGS. 10B to 10F above.

Comparing the fabrication method shown in FIGS. 10A to 10F to the methods shown in FIGS. 2A to 2H and FIG. 5, there is no formation of a trench in the method shown in FIGS. 10A to 10F to remove the sacrificial first layers (1002a, 1004a and 1006a). In FIGS. 10A to 10F, a layer-by-layer etching method is used.

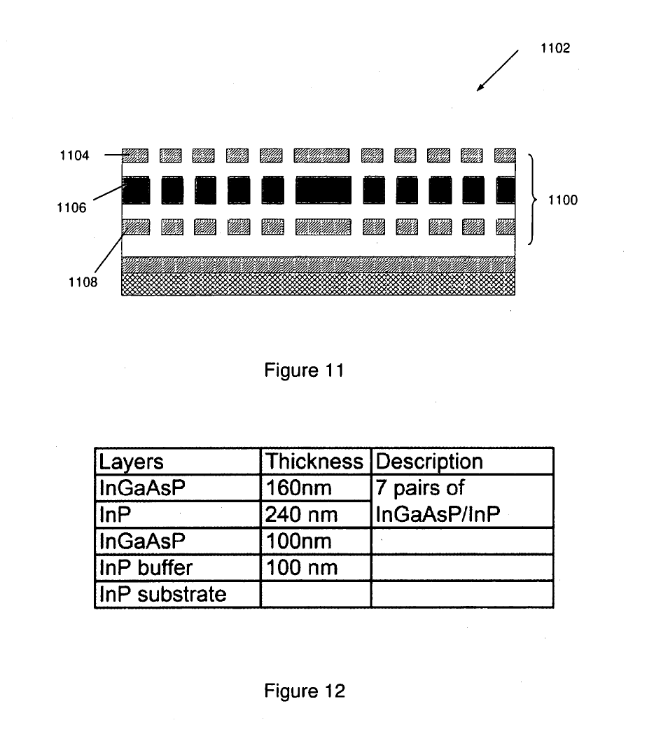

FIG. 11 shows a cross-sectional view of a 3D photonic crystal 1102 formed in accordance to one embodiment of the invention.

The properties of the 3D photonic crystal 1102 may be easily modified by introducing different materials or different thickness for each layer 1104, 1106 and 1108 of a multi-layer stack 1100 semiconductor sample during epitaxy growth. For example, the central layer 1106 in a vertical direction of the 3D photonic crystal 1102 structure may have an InGaAs or InGaAsP layer with a photonic bandgap of 1.55 um (i.e. in terms of wavelength), while the other InGaAsP layers (1104 and 1108) respectively above and beneath the central layer 1106 may have a photonic bandgap of 1.15 um. The central InGaAs or InGaAsP layer 1106 will then have a larger refractive index and absorption/amplification property for light propagation at a wavelength of 1.55 um, acting as a defect layer for the photonic crystal 1102. It is also possible to make all the layers (1104, 1106 and 1108) different in terms of thickness, bandgap, refractive index, etc, in one growth, which is an advantage of the present invention. The pseudo-point defect or line defect can also be introduced through top 2D patterning.

In embodiments of the present invention, removing of the at least one portion (202p, 204p and 206p; 502t, 504t and 506t; 702p, 704p and 706p; 1002p, 1004p and 1006p) of the second layer (202b, 204b and 206b; 502b, 504b and 506b; 702b, 704b and 706b; 1002b, 1004b and 1006b) and removing of the first layer (202a, 204a and 206a; 1002a, 1004a and 1006a) is performed such that a gap exists between adjacent remaining portions of the second layer.

In embodiments of the present invention, removing of the at least one portion (202p, 204p and 206p; 502t, 504t and 506t; 702p, 704p and 706p; 1002p, 1004p and 1006p) of the second layer (202b, 204b and 206b; 502b, 504b and 506b; 702b, 704b and 706b; 1002b, 1004b and 1006b) and removing of the first layer (202a, 204a and 206a; 1002a, 1004a and 1006a) is performed by any one of the following procedures: etching or ion milling. The etching may either be a dry etch or a wet etch.

In embodiments of the present invention, within each partial layer arrangement, the first layer (202a, 204a and 206a; 1002a, 1004a and 1006a) and the second layer (202b, 204b and 206b; 502b, 504b and 506b; 702b, 704b and 706b; 1002b, 1004b and 1006b) may be in contact with each other.

Notwithstanding the materials, along with their respective parameters, presented thus far to fabricate a stacked chip arrangement using methods in accordance to embodiments of the invention, a stacked chip arrangement built in accordance to the invention may be composed of the following materials and have the following respective parameters.

The first layer (202a and 1002a) of the first partial layer arrangement (202 and 1002) may use the same material as the first layer (204a and 1004a) of the second partial layer arrangement (204 and 1004). The second layer (202b, 702b and 1002b) of the first partial layer arrangement (202, 702 and 1002) may use the same material as the second layer (204b, 704b and 1004b) of the second partial layer arrangement (204, 704 and 1004).

In embodiments of the present invention, the first layer (202a, 204a and 206a; 1002a, 1004a and 1006a) may include InP, GaAs or Si. The second layer (202b, 204b and 206b; 502b, 504b and 506b; 702b, 704b and 706b; 1002b, 1004b and 1006b) may include InGaAsP, InAlGaAs, AlGaAs, InGaAs, InGaNAs, SiC or SiGe. The material for the first layer (202a, 204a and 206a; 1002a, 1004a and 1006a) may be exchanged with the material for the second layer (202b, 204b and 206b; 502b, 504b and 506b; 702b, 704b and 706b; 1002b, 1004b and 1006b). Thus, in other embodiments of the present invention, the first layer (202a, 204a and 206a; 1002a, 1004a and 1006a) may include InGaAsP, InAlGaAs, AlGaAs, InGaAs, InGaNAs, SiC or SiGe. The second layer (202b, 204b and 206b; 502b, 504b and 506b; 702b, 704b and 706b; 1002b, 1004b and 1006b) may include InP, GaAs or Si. The substrate (208, 508, 708 and 1008) may be InP, GaAs or Si.

FIG. 12 shows a table summarising InGaAsP and InP thicknesses for a 3D photonic crystal (such as 270, 570, 602, 604, 770, 1070 and 1102) fabricated on an InGaAsP/InP multi-layer structure grown by MOCVD. A 100 nm InP buffer layer and a 100 nm InGaAsP are grown sequentially on top of a [1, 0, 0] InP substrate. After that, 7 pairs of InGaAsP (160 nm)/InP (240 nm) stack layer are grown on the substrate. It will be appreciate that more than 7 pairs of InGaAsP/InP layers may be used, depending on user and design requirements.

While FIG. 12 shows that each layer in an InGaAsP/InP pair (i.e. the first layer and the second layer of a partial layer arrangement) has the same thickness, in embodiments of the present invention, the thicknesses of the first layer (202a, 204a and 206a; 1002a, 1004a and 1006a) and the second layer (202b, 204b and 206b; 502b, 504b and 506b; 702b, 704b and 706b; 1002b, 1004b and 1006b) may be different.

In embodiments of the present invention, the patterned mask (210p, 510p, 710p and 1010p) may include any one or more of photoresist, silicon dioxide, silicon nitride, metal or dielectric material.

The above embodiments of the present invention facilitate the following, along with their respective advantages:
1. one step plasma etching on a 1D multi-layer semiconductor
Advantage: the plasma etching is easy and simple
2. repeated layer-by-layer plasma-chemical etching
Advantages: no alignment to crystal orientation, simpler and more maneuverable than like layer-by-layer etch and regrowth methods
3. a one tilt etch to change the lattice structure and increase choices of photonic crystal structures that may be created
4. Proposed introducing defects through either
   vertical direction during material growth by changing material composition, layer thickness, spacing
   or lateral direction during 2D patterning
5. Defect layers may act as absorption material to propagating light of a selected wavelength or gain material to amplify propagating light of a selected wavelength.
6. Control feature size and periodicity in the lateral and transverse directions by 2D nano-patterning. A special point or line defect can be created by patterning or by combining with the vertical growth.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A method of forming photonic crystals, the method comprising:
forming a layer arrangement on a support substrate, the layer arrangement comprising a first partial layer arrangement and a second partial layer arrangement,
wherein the second partial layer arrangement is disposed over the first partial layer arrangement,
wherein each partial layer arrangement comprises a first layer and a second layer,
wherein the second layer is disposed over the first layer for each partial layer arrangement, and
wherein the material of the second layer has a different etching characteristic than the material of the first layer for each partial layer arrangement; and
wherein the layer arrangement is formed prior to removing at least one portion of the second layer and the first layer defined by the operations comprising:
removing at least one portion of the second layer of the second partial layer arrangement;
removing at least the first layer of the second partial layer arrangement; and
removing at least one portion of an adjacent second layer after removing the first layer.

2. The method of claim 1, further comprising
disposing a mask over the second layer of the second partial layer arrangement; and
developing a pattern on the mask, the patterned mask facilitating removal of the at least one portion of the second layer.

3. The method of claim 2, wherein disposing the mask occurs after forming the layer arrangement.

4. The method of claim 2, wherein the patterned mask is removed after the photonic crystals are formed.

5. The method of claim 2, wherein removing of the at least one portion of the second layer of the second partial layer arrangement occurs before removing the first layer.

6. The method of claim 2, wherein removing the first layer occurs before removing the at least one portion of the second layer of the second partial layer arrangement.

7. The method of claim 6, wherein removing the first layer comprises removing the first layer of the first partial layer arrangement and the first layer of the second partial layer arrangement in a single operation.

8. The method of claim 6, further comprising
forming a trench extending through the layer arrangement to a surface of the support substrate, the trench facilitating removing the first layer in a direction perpendicular to the direction the trench is formed.

9. The method of claim 8, wherein forming the trench occurs after forming the layer arrangement.

10. The method of claim 6, wherein developing the pattern on the mask occurs after removing the first layer.

11. The method of claim 2, wherein developing a pattern on the mask occurs before removing the at least one portion of the second layer and removing the first layer.

12. The method of claim 1, wherein removing of the at least one portion of the second layer and removing of the first layer are performed such that a gap exists between adjacent remaining portions of the second layer.

13. The method of claim 1, wherein the layer arrangement comprises a plurality of the first partial layer arrangement and a plurality of the second partial layer arrangement, wherein removing of the at least one portion of the second layer and removing of the first layer are reiterated on both the plurality of the first partial layer arrangement and the plurality of the second partial layer arrangement.

14. The method of claim 1, wherein removing of the at least one portion of the second layer is performed by any one of the procedures of plasma etching, focused ion beam etching or ion milling.

15. The method of claim 1, wherein removing of the first layer is performed by chemical etching.

16. The method of claim 1, wherein the thicknesses of the first layer and the second layer are either the same or different.

17. The method of claim 1, wherein within each partial layer arrangement, the first layer and the second layer are in contact with each other.

18. The method of claim 1, wherein the first layer of the first partial layer arrangement comprises the same material as the first layer of the second partial layer arrangement.

19. The method of claim 1, wherein the second layer of the first partial layer arrangement comprises the same material as the second layer of the second partial layer arrangement.

20. The method of claim 1, wherein the second layer of the first partial layer arrangement comprises a different material than the second layer of the second partial layer arrangement.

21. The method of claim 1, wherein the first layer comprises any one of InP, GaAs, or Si.

22. The method of claim 1, wherein the second layer comprises any one of InGaAsP, InGaAlAs, AlGaAs, InGaAs, InGaNAs, SiC or SiGe.

23. The method of claim 1, wherein the second layer comprises any one of InP, GaAs, or Si.

24. The method of claim 1, wherein the first layer comprises any one of InGaAsP, InGaAlAs, AlGaAs, InGaAs, InGaNAs, SiC or SiGe.

25. The method of claim 2, wherein the patterned mask comprises any one or more of photoresist, silicon dioxide, silicon nitride, metal or dielectric material.

26. The method of claim 1, wherein
removing of the at least one portion of the second layer is such that, along an axis perpendicular to a surface of the support substrate, at least one location where the portion of a second layer is removed is aligned with a remaining portion of an adjacent second layer.

27. The method of claim 1, further comprising tilting the support substrate.

28. The method of claim 27, wherein the angle of tilt is around 20° to 70°.
